(19) United States
(12) Patent Application Publication
(10) Pub. No.: US 2026/0333813 A1
(43) Pub. Date: Oct. 22, 2026

(54) METHODS FOR FABRICATING CONTACT STRUCTURES

(71) Applicant: Tokyo Electron Limited, Tokyo (JP)

(72) Inventors: Ryota Yonezawa, Albany, NY (US); Tadahiro Ishizaka, Nirasaki City (JP); Kai-Hung Yu, Albany, NY (US); Hidenao Suzuki, Albany, NY (US)

(21) Appl. No.: 19/184,215

(22) Filed: Apr. 21, 2025

(51) Int. Cl. H01L 21/285; H10D 84/01

(52) U.S. Cl. CPC H10D 64/0112; H10D 84/013; H10D 84/0149

(57) ABSTRACT

A method is provided for processing a substrate. The method includes loading a substrate in a process chamber, where the substrate includes a recessed feature and a silicon-containing layer disposed at the bottom of the recessed feature. The method further includes forming a metal-containing layer over the silicon-containing layer, where the metal-containing layer includes a surface layer containing halogen. The method also includes exposing the metal-containing layer to a nitrogen-containing gas to remove the halogen from the surface layer. Additionally, the method includes forming a metal layer over the metal-containing layer, where the metal layer fills the recessed feature.

### TECHNICAL FIELD

The present invention relates generally to a method for semiconductor device manufacturing, and, in particular embodiments, to a method for fabricating metal contacts.

### BACKGROUND

Semiconductor device manufacturing involves multiple processing steps for forming electrical contacts and interconnects between device regions. Metal-semiconductor interfaces are particularly important for device performance, where oxidation between processing steps may lead to increased contact resistance and degraded device characteristics.

As semiconductor devices scale to smaller dimensions, contact formation faces increasing challenges that require more precise control of interface properties. The reduced size of contact features makes them more sensitive to surface conditions, where even minimal oxidation or contamination can significantly impact electrical performance. Traditional plasma-based surface treatments, while effective for larger features, may not provide adequate control for current and future device nodes where contact resistance has become a limiting factor in device performance.

### SUMMARY

In accordance with one aspect of the present invention, a method is provided for processing a substrate. The method includes loading a substrate in a process chamber, where the substrate comprises a recessed feature and a silicon-containing layer disposed at the bottom of the recessed feature. A metal-containing layer is formed over the silicon-containing layer, with the metal-containing layer comprising a surface layer comprising halogen. The metal-containing layer is exposed to a nitrogen-containing gas to remove the halogen from the surface layer. A metal layer is then formed over the metal-containing layer, wherein the metal layer fills the recessed feature.

In accordance with another aspect of the present invention, a method is provided for processing a substrate. The method includes providing a substrate comprising a silicon-containing layer in a process chamber. A metal-containing layer is formed over the silicon-containing layer. The metal-containing layer is annealed to form a titanium silicide layer. A thermal process is performed in the absence of plasma, which includes exposing the titanium silicide layer to a nitrogen-containing gas to form a nitrogen-containing surface layer in the titanium silicide layer. A metal layer is then formed over the nitrogen-containing surface layer.

In accordance with yet another aspect of the present invention, a method is provided for processing a substrate. The method includes loading a substrate in a process chamber, where the substrate comprises a patterned mask layer disposed over a layer to-be-etched. The layer to-be-etched is etched through an opening of the patterned mask layer to form an etched layer. A first metal-containing layer is formed over surfaces of the etched layer, with the first metal-containing layer comprising halogen. The substrate is exposed to a nitrogen-containing gas to remove the halogen from the first metal-containing layer. A second metal-containing layer is then deposited over the first metal-containing layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate cross-sectional views of process steps in forming a contact structure in a substrate with a thermal treatment, in accordance with an embodiment;

FIG. 2 illustrates a top view of the substrate corresponding to FIG. 1A, showing gate materials, in accordance with an embodiment;

FIGS. 3A-3B illustrate cross-sectional views of a process variation showing removal of surface oxide formation, in accordance with an embodiment;

FIG. 4 illustrates a cross-sectional view showing a variation of thermal treatment of FIG. 1C, in accordance with an embodiment;

FIGS. 5A-5B illustrate exemplary experimental data demonstrating thermal treatment effects of removing chlorine, in accordance with an embodiment;

FIGS. 6A-6B illustrate exemplary experimental data demonstrating thermal treatment effects of reducing nitrogen amount, in accordance with an embodiment;

FIGS. 7A-7B illustrate exemplary experimental data demonstrating thermal treatment effects of protecting substrate from surface oxidation, in accordance with an embodiment;

FIGS. 8A-8F illustrate cross-sectional views of process steps for processing a substrate with high aspect ratio feature, in accordance with an embodiment;

FIG. 9 is an exemplary illustration of disadvantage using conventional plasma treatment method, in accordance with an embodiment;

FIG. 10 illustrates a process flow diagram for processing a substrate to form contact structures, in accordance with an embodiment; and

FIG. 11 illustrates another process flow diagram for processing a substrate to form contact structures, in accordance with an embodiment.

### DETAILED DESCRIPTION OF ILLUSTRATIVE EMBODIMENTS

Source and drain contacts in semiconductor devices provide electrical connections to the active regions of transistors. Titanium silicide (TiSiₓ) processes are widely implemented for these contacts due to their low contact resistance and good thermal stability. The formation of high-quality titanium silicide contacts is essential for optimal device performance.

A protective nitrogen cap on titanium silicide surfaces may prevent oxidation and remove chlorine contamination from previous processing steps. Conventional approaches utilize nitrogen-containing plasma during deposition for this purpose. However, these plasma-based methods often result in excessive nitrogen and chlorine incorporation into the titanium silicide layer, leading to increased contact resistance and compromised subsequent metal deposition.

In various embodiments, a thermal treatment process utilizing nitrogen-containing gases such as hydrazine (N₂H₄) is performed after titanium silicide formation. Because, in various embodiments, the thermal treatment process is a non-plasma process, this thermal process may provide controlled nitrogen content while effectively removing chlorine from the titanium silicide surface. The hydrazine treatment is compatible with metal deposition processes using halogen-containing precursors for various metals including zirconium (Zr), niobium (Nb), hafnium (Hf), molybdenum (Mo), titanium (Ti), tungsten (W), nickel (Ni), and tantalum (Ta). The thermal treatment process may effectively clean halogen, e.g. chlorine, from both metal and dielectric surfaces while forming a protective layer against reoxidation.

In one or more embodiments, the thermal treatment process may provide uniform treatment on all surfaces within high aspect ratio features. This conformal coverage enables consistent chlorine removal throughout the feature geometry, resulting in improved uniformity of subsequent metal deposition. The controlled nitrogen content and efficient chlorine removal lead to enhanced contact performance in advanced semiconductor devices.

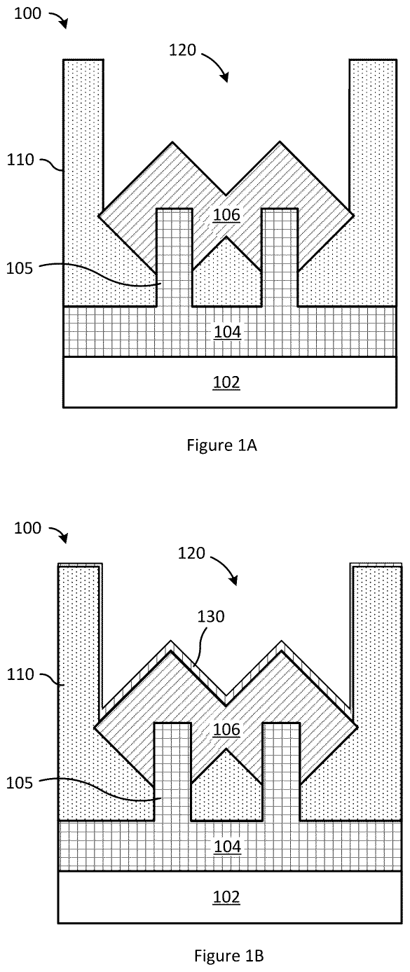

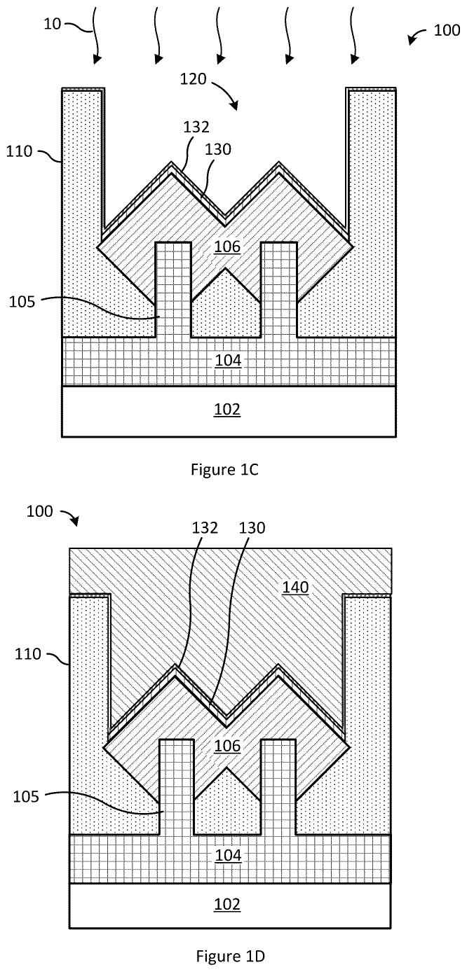

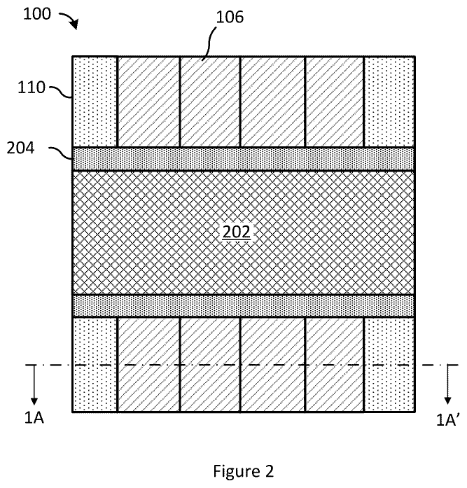

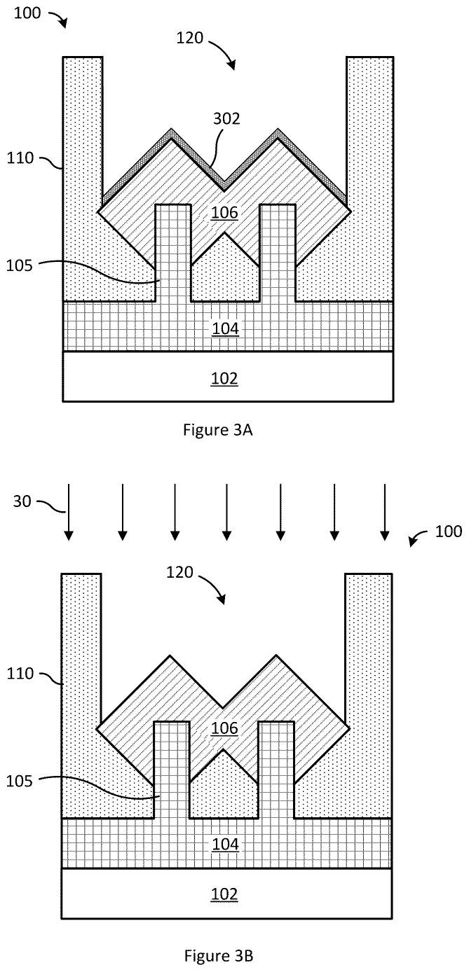

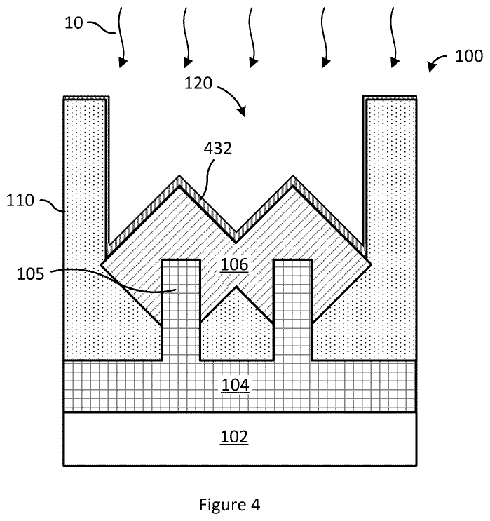

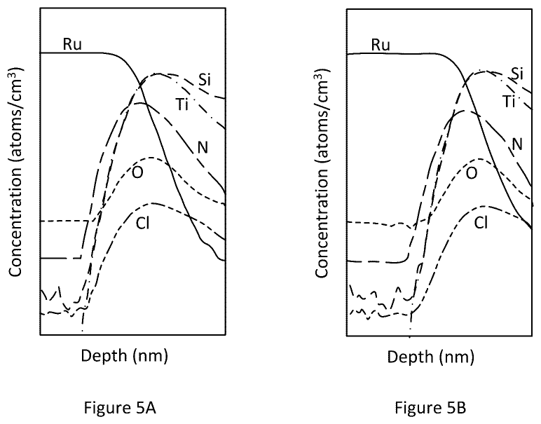

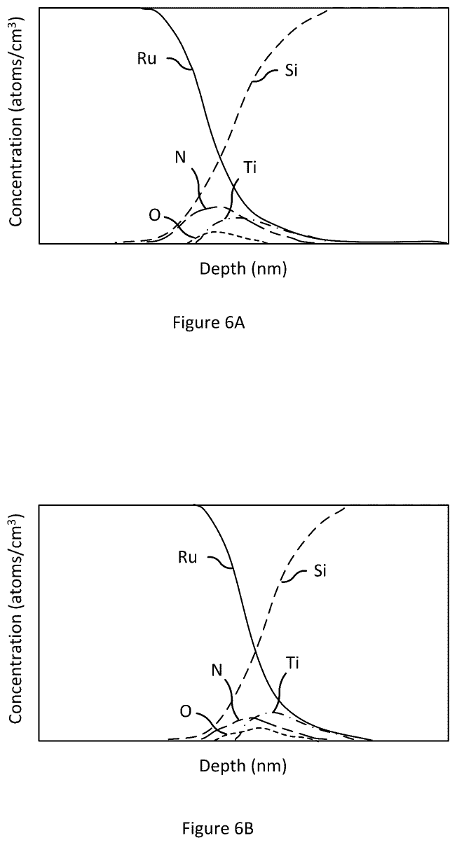

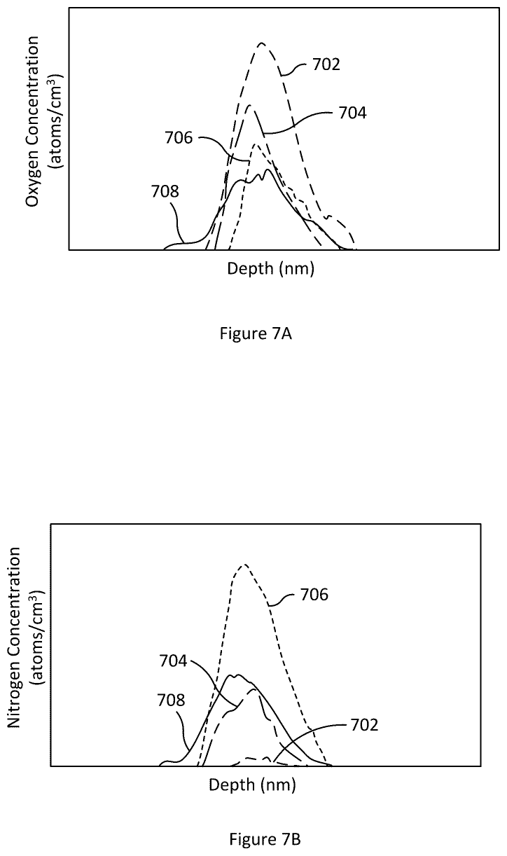

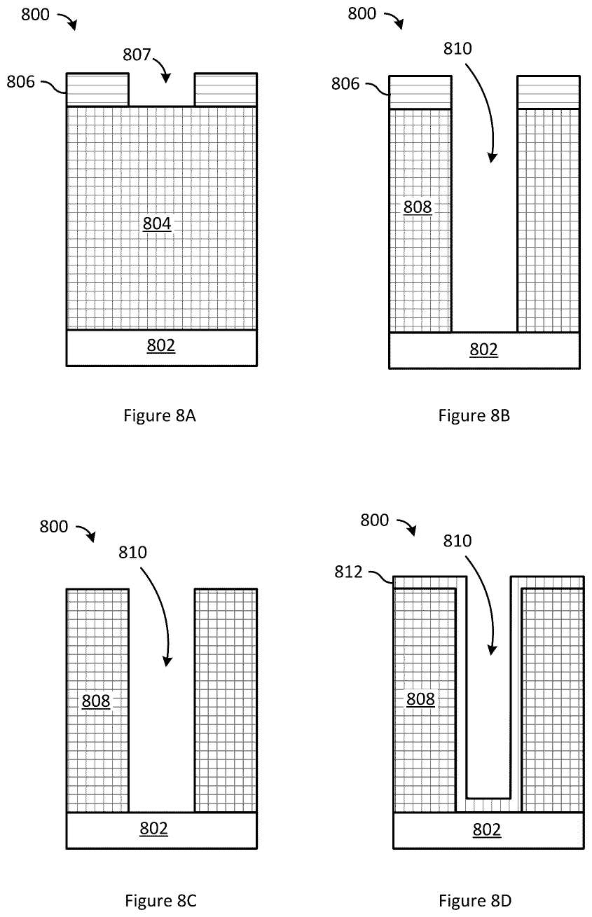

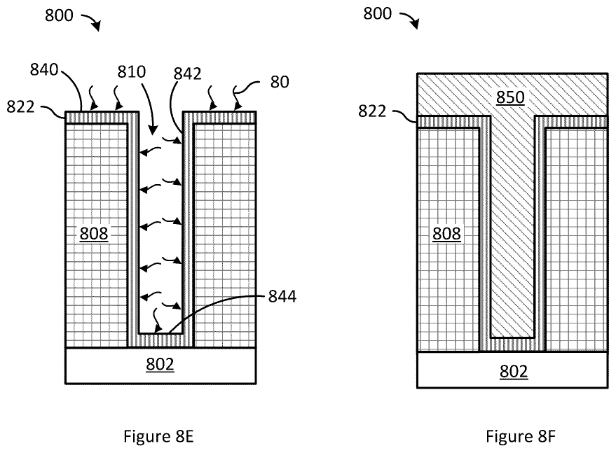

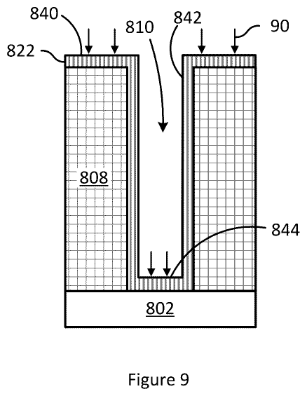

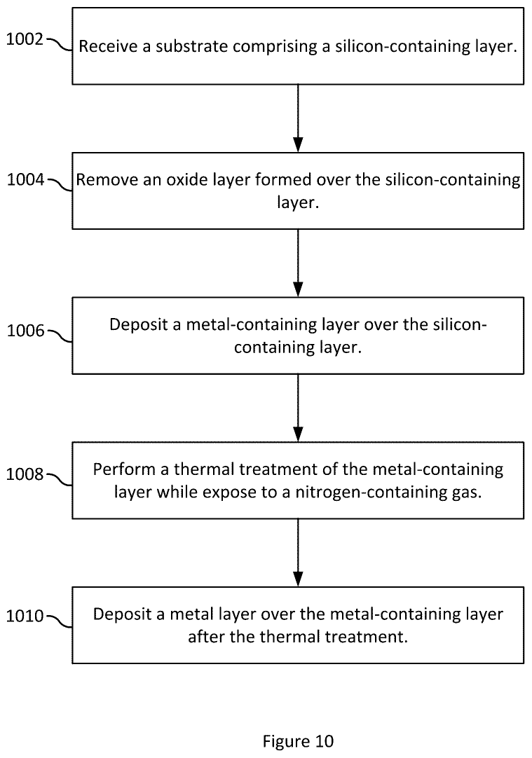

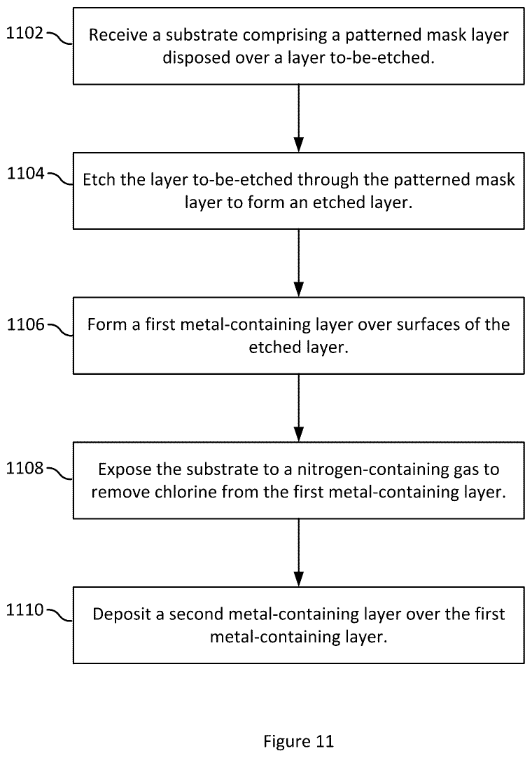

Embodiments of the disclosure are described in the context of the accompanying drawings. An embodiment of process steps for forming contact structures in a substrate is described using FIGS. 1A-1D. A top view of the substrate in FIG. 1A is shown in FIG. 2. A process of removing substrate surface oxide is shown in FIGS. 3A-3B. A variation of thermal treatment on the substrate is illustrated in FIG. 4. Experimental data demonstrating thermal treatment effects of removing chlorine are illustrated in FIGS. 5A-5B. Experimental data demonstrating thermal treatment effects of reducing nitrogen amount are illustrated in FIGS. 6A-6B. Experimental data demonstrating thermal treatment effects of protecting substrate from surface oxidation are illustrated in FIGS. 7A-7B. An embodiment of process steps for processing a substrate with high aspect ratio feature is described using FIGS. 8A-8F. An exemplary illustration of disadvantage using conventional plasma treatment method is shown in FIG. 9. Process flow diagrams for different substrate processing methods are presented in FIGS. 10 and 11.

FIGS. 1A-1D illustrate cross-sectional views of a process flow for processing a substrate to form contact structures, in accordance with an embodiment. In various embodiments, a thermal treatment process using nitrogen-containing gas may be applied between forming two contact layers to provide surface protection while efficiently removing halogen (e.g., chlorine) contamination from previous processing steps. The thermal treatment process may produce a controlled nitrogen-containing surface layer that prevents oxidation while maintaining low overall nitrogen content.

In FIG. 1A, a substrate 100 may be loaded in a process chamber. The substrate 100 may comprise a substrate layer 102 over which a fin structure 104 may be formed. The fin structure 104 may comprise fin features 105 that extend vertically from the substrate. A silicon-containing layer 106 may be formed over the fin features 105. A dielectric structure 110 may be disposed adjacent to the fin structure 104 for electrical isolation. A recessed feature 120 may be formed in the substrate 100 and surrounded by the dielectric structure 110, which provides an area for subsequent contact formation. The silicon-containing layer 106 may be disposed at bottom of the recessed feature 120. The dielectric structures 110 and recessed feature 120 may define regions where electrical contacts will be formed to the silicon-containing layer 106. In various embodiments, the dielectric structures 110 may comprise silicon oxide, silicon nitride, or other insulating materials.

In various embodiments, the substrate 100 may be a portion of a FinFET or other field effect transistor structure. FIG. 1A illustrates a cross-sectional view taken along line 1A-1A′ shown in FIG. 2, where FIG. 2 is a top view of the substrate 100 in FIG. 1A. In one or more embodiments, a gate structure 202 may be disposed over the fin features 105, comprising a gate dielectric layer and a metal gate electrode. In various embodiments, the gate dielectric may include high-k dielectric materials such as hafnium oxide, hafnium silicon oxide, or other metal oxides. The metal gate electrode may comprise one or more metal layers such as titanium nitride, tungsten, aluminum, or other work function metals selected for optimal device performance. The gate structure 202 may wrap around three sides of the fin features 105 to provide enhanced electrostatic control of the channel region.

In various embodiments, the silicon-containing layer 106 may be epitaxially grown on the fin features 105 to form raised source and drain regions disposed on opposite sides of the gate structure 202. The source and drain regions may serve as components in the transistor operation by forming the terminals where current enters and exits the device. During transistor operation, the source region may provide carriers (electrons for NMOS or holes for PMOS) that flow through the channel region beneath the gate structure 202, while the drain region collects these carriers, enabling current flow through the device. In various embodiments, the silicon-containing layer 106 may be selectively doped with n-type dopants (such as phosphorus or arsenic) for NMOS devices or p-type dopants (such as boron or gallium) for PMOS devices to enhance conductivity. The composition and doping of the silicon-containing layer 106 may include doped silicon, silicon-germanium (SiGe), silicon-phosphorus (SiP), or combinations thereof, selected to optimize carrier mobility and minimize contact resistance.

In various embodiments, the silicon-containing layer 106 may exhibit distinctive geometric features formed through selective epitaxial growth. In cross-sectional view, the silicon-containing layer 106 may have a faceted diamond-like shape profile extending outward and upward from the fin features 105. The faceted surfaces may be formed naturally during the epitaxial growth process due to different growth rates along various crystallographic planes of the silicon-based material. These angled surfaces may form at specific crystallographic angles relative to the substrate surface. The upper portions of the silicon-containing layer 106 are wider than the fin features 105, creating an expanded region that increases the contact area available for subsequent metal contact formation. This expanded profile, combined with the faceted surfaces, helps reduce contact resistance by providing larger interface areas for electrical connections. In various embodiments, the specific angles and dimensions of these faceted surfaces may be controlled through epitaxial growth conditions to optimize device performance while maintaining proper spacing between adjacent source/drain regions.

In various embodiments, spacer layers 204 may be formed along sidewalls of the gate structure 202 to electrically isolate the gate from the source/drain regions. The spacer layers 204 may comprise silicon nitride, silicon oxide, or multiple layers of different dielectric materials. These spacers serve multiple functions: they protect the gate during processing, define the separation between gate and source/drain regions, and help control dopant placement during formation of the silicon-containing layer 106. In some embodiments, the silicon-containing layer 106 may epitaxially grown in regions defined by the spacer layers 204, forming raised source and drain regions with controlled proximity to the gate structure 202.

Refer back to FIG. 1A, the fin structures 104 may be formed through etching processes. The fin structures 104 may comprise single-crystal silicon, though in various embodiments may also be formed from silicon-germanium or other semiconductor materials suitable for channel formation. While FIG. 1A shows two fin features 105 for illustration, the structure may include multiple fin features arranged in parallel, with three, four, or more fins depending on the desired device characteristics. The multiple fin configuration increases the effective channel width and thus drives current capability of the device without significantly increasing the lateral device footprint. Each fin feature 105 may extend vertically from the substrate surface with a controlled height and width, having an aspect ratio suitable for optimal gate control. The spacing between adjacent fin features 105 may be precisely controlled to maintain proper device isolation while maximizing device density. The top and sidewall surfaces of the fin features 105 may serve as channel regions when covered by the gate structure 202, providing enhanced current flow through multiple surfaces compared to planar transistor designs.

In various embodiments, the substrate layer 102 may comprise a bulk substrate such as a blank silicon wafer, a silicon-on-insulator (SOI) wafer, or any of various other semiconductor substrates. The substrate layer 102 may also be coated or layered with any number of additional materials, including compound semiconductors, metal or metal oxides, or metal nitrides. The substrate layer 102 may include any material portion or structure of a device, particularly a semiconductor or other electronics device.

In some embodiments, an oxide layer 302 may form over surfaces of the silicon-containing layer 106 as illustrated in FIG. 3A. In various embodiments, the oxide layer 302 may form naturally when the silicon-containing surfaces are exposed to ambient conditions or during various processing steps. The oxide formation may occur through spontaneous oxidation of the silicon-containing material when exposed to oxygen or moisture in the environment. This native oxide layer 302 may comprise silicon dioxide (SiO₂) and may form with varying thickness depending on exposure conditions and duration. In one or more embodiments, the oxide layer 302 may further comprise other elements present in the silicon-containing layer 106, such as germanium or dopants, potentially forming more complex oxide compositions. The presence of oxide layer 302 may interfere with subsequent processing steps, particularly affecting the quality of metal contact formation. While natural oxide formation is difficult to prevent completely during fabrication processes, its removal is important for achieving low-resistance contacts.

FIG. 3B illustrates a cross-sectional view showing application of an etching process 30 to remove the oxide layer 302 from the surfaces of silicon-containing layer 106. In various embodiments, the oxide removal may be performed using chemical oxide removal (COR) processes, which may provide controlled and selective oxide etching. The COR process may utilize gas-phase chemical treatments such as HF vapor, or combinations of HF and NH₃ vapors, which selectively react with and remove the oxide while minimizing impact to underlying materials.

Alternative etching methods may include wet chemical treatments using dilute HF solutions, buffered oxide etch (BOE) solutions, or other selective oxide etchants. In one or more embodiments, plasma-based treatments using hydrogen-containing plasmas or remote plasma processes may also be employed. The etching process 30 parameters such as temperature, pressure, and duration are controlled to ensure complete removal of the oxide layer 302 while maintaining the desired profile of the silicon-containing layer 106. The removal of oxide layer 302 provides a clean surface for subsequent processing steps, particularly important for achieving low-resistance contacts in later stages of device fabrication.

In FIG. 1B, a metal-containing layer 130 may be formed over the silicon-containing layer 106. In some embodiments, the metal-containing layer 130 may also be formed over side walls and top surfaces of the dielectric structure 110. In various embodiments, the metal-containing layer 130 may be formed by exposing the substrate 100 to metal halide precursors comprising chlorine, fluorine, bromine, or iodine. The metal-containing layer 130 may comprise metals such as zirconium (Zr), niobium (Nb), hafnium (Hf), molybdenum (Mo), titanium (Ti), tungsten (W), nickel (Ni), tantalum (Ta), or the like. In one or more embodiments, the metal-containing layer 130 may be formed from metal chloride precursors such as titanium tetrachloride (TiCl₄), zirconium tetrachloride (ZrCl₄), niobium pentachloride (NbCl₅), hafnium tetrachloride (HfCl₄), molybdenum pentachloride (MoCl₅), tungsten hexachloride (WCl₆), nickel chloride (NiCl₂), tantalum pentachloride (TaCl₅), or the combination thereof. In various embodiments, the metal halide precursors may also comprise metal fluoride, metal bromide, or metal iodide. The selection of metal precursors depends on the desired metal composition in the metal-containing layer 130.

In various embodiments, the metal-containing layer 130 may be deposited using various techniques including chemical vapor deposition (CVD), atomic layer deposition (ALD), or physical vapor deposition (PVD) methods. In various embodiments, CVD techniques may include thermal CVD, plasma-enhanced CVD (PECVD), metal-organic CVD (MOCVD), or hot-wire CVD. ALD methods may include thermal ALD, plasma-enhanced ALD, or spatial ALD. PVD processes may include magnetron sputtering, direct current sputtering, radio frequency sputtering, or electron beam evaporation. The selection of deposition method depends on requirements for step coverage, deposition rate, and film purity for specific device applications.

In certain embodiment, the metal-containing layer 130 may comprise titanium and the deposition may be performed using CVD or ALD with titanium TiCl₄ as the halogen precursor. In these processes, TiCl₄ vapor may introduced into the process chamber where it reacts to form a titanium layer on the substrate surface. The deposition may be enhanced through plasma activation or thermal energy, with precise control of process parameters including temperature, pressure, and gas flows.

During deposition of the metal-containing layer 130, residual halogen (e.g., chlorine, fluorine, bromine, or iodine) from the metal halogen precursors may remain in the deposited film, necessitating subsequent treatment steps for halogen removal. In one or more embodiments, the metal-containing layer 130 may comprise a surface layer with higher concentration of halogen due to incomplete precursor decomposition or reaction byproduct adsorption during the final stages of deposition. In an embodiment of the TiCl₄-based deposition process, chlorine may incorporate into the titanium layer. The presence of residual chlorine may impact the quality of subsequent titanium silicide (TiSi) formation and increase contact resistance. Conventional processes may introduce nitrogen-containing plasma during deposition to remove chlorine and add nitrogen atoms into the metal-containing layer 130 to prevent reoxidation. However, this method often results in excessive nitrogen content, which may degrade contact performance.

In various embodiments, after depositing the metal-containing layer 130, an annealing process may be performed to diffuse silicon atoms in the silicon-containing layer 106 into the metal-containing layer 130. The titanium atoms in the metal-containing layer 130 may also diffuse into the silicon-containing layer 106. This inter-diffusion and reaction at the interface may convert the metal-containing layer 130 into a titanium silicide layer, which provides a low-resistance interface essential for electrical contact between the silicon-containing regions and subsequent metal contacts.

FIG. 1C illustrates a thermal treatment process 10 performed on the substrate 100 after forming the metal-containing layer 130. In various embodiments, a temperature of the process chamber may be elevated and maintained at between 100 °C and 400 °C during the thermal treatment. In alternative embodiments, the substrate 100 may be heated through a temperature-controlled substrate holder, which may comprise a heating element embedded within a support pedestal. The substrate holder may include features such as lift pins, electrostatic chuck capabilities, and temperature monitoring devices to maintain precise thermal control.

In various embodiments, the thermal treatment process 10 may comprise flowing a nitrogen-containing gas over the substrate surface. In one or more embodiments, the nitrogen-containing gas may comprise hydrazine (N₂H₄), ammonia (NH₃), nitrogen (N₂), methylhydrazine (CH₃NHNH₂), dimethylhydrazine ((CH₃)₂NNH₂), diazene (N₂H₂), triazane (N₃H₅), tetrazane (N₄H₆), alkylhydrazines, monomethylhydrazine (MMH), unsymmetrical dimethylhydrazine (UDMH), ethylhydrazine, or other hydrazine derivatives. The gas flow rate may be maintained between 50 sccm and 200 sccm to ensure uniform surface treatment. In one or more embodiments, carrier gases such as argon, helium, or hydrogen may be introduced along with the nitrogen-containing gas.

In various embodiments, the thermal treatment process 10 may result in two primary effects: incorporation of nitrogen into the metal-containing layer 130 (or the titanium silicide layer in embodiments where silicidation has occurred) and removal of residual halogen (e.g., chlorine) from previous processing steps. The thermal treatment process 10 may form a nitrogen-containing surface layer 132 at the upper portion of the metal-containing layer 130. The nitrogen-containing surface layer 132 may serve as a protective cap that prevents oxidation of underlying materials while maintaining controlled nitrogen content at the interface. The thermal nature of the process allows for uniform treatment across complex surface topographies.

FIG. 4 illustrates a cross-sectional view showing an alternative result of the thermal treatment process 10, where nitrogen diffusion occurs throughout the metal-containing layer 130 to form a nitridated metal-containing layer 432. Unlike the surface-localized nitrogen incorporation shown in FIG. 1C, in this embodiment, nitrogen atoms may diffuse deeper into the metal-containing layer 130. The nitrogen concentration may exhibit a gradient profile, with higher concentration near the surface decreasing toward the interface with the underlying silicon-containing layer 106. In one or more embodiments, the nitrogen gradient in nitridated metal-containing layer 432 may be controlled to help optimize adhesion at the upper interface while minimizing impact on electrical properties at the lower interface.

In FIG. 1D, a metal layer 140 may be formed over the metal-containing layer 130 (or the nitridated metal-containing layer 432). In various embodiments, the metal layer 140 may comprise tungsten, copper, ruthenium, or molybdenum. The deposition method for the metal layer 140 varies depending on the selected metal material. In various embodiments, the deposition method may be selected from the methods described to deposit the metal-containing layer 130.

In some embodiments, the metal layer 140 may comprise ruthenium. In various embodiments, ruthenium deposition may be performed using atomic layer deposition (ALD) or chemical vapor deposition (CVD) processes with ruthenium-containing precursors. The precursors may comprise ruthenium organometallic compounds such as bis(ethylcyclopentadienyl)ruthenium (Ru(EtCp)₂), bis(cyclopentadienyl)ruthenium (RuCp₂), tris(2,2,6,6-tetramethyl-3,5-heptanedionato)ruthenium, or ruthenium carbonyl compounds (e.g., Ru₃(CO)₁₂). In one or more embodiments, the ruthenium precursor may be delivered with co-reactants such as oxygen, hydrogen, or ammonia to enhance the deposition process. The nitrogen-containing surface layer 132 formed in the previous step provides excellent adhesion for ruthenium growth while preventing oxidation at the interface. Process parameters including temperature (e.g., 200-400 °C), pressure, and precursor delivery are controlled to achieve conformal and void-free ruthenium fill of the recessed features 120. The resulting ruthenium metal layer 140 may provide low-resistance electrical contacts to the underlying device regions.

Though not explicitly illustrated in the figures, various intermediate process steps may be performed between the major processing steps described above. These intermediate steps may include in-situ or ex-situ cleaning processes, chamber purging operations, and transfers between different process chambers in a multi-chamber processing system. In various embodiments, plasma treatments may be applied during certain process steps when needed, such as surface activation or cleaning. Gas purge steps may be performed between reactive gas exposures to remove residual reactants and byproducts. While the formation of titanium silicide is described in detail, similar processes may be applied to form other metal silicides using different metal-containing layers. For example, the thermal treatment process 10 may be applied to silicides formed from zirconium, niobium, hafnium, molybdenum, tungsten, nickel, tantalum, or combinations thereof. The specific process parameters such as temperature, pressure, gas flows, and treatment durations may be adjusted according to the particular metal silicide being formed while maintaining the benefits of controlled nitrogen content and efficient halogen removal.

FIGS. 5A and 5B present Secondary Ion Mass Spectrometry (SIMS) depth profiles comparing chlorine removal effectiveness between different treatment methods, in accordance with an embodiment. The profiles show elemental concentrations (atoms/cm³) on a logarithmic scale versus depth (nm) through a contact structure comprising the metal layer 140, the metal-containing layer 130, and the silicon-containing layer 106, in which the metal layer 140 comprises ruthenium and the metal-containing layer 130 comprises titanium. The contact structure may include transitions between ruthenium, titanium silicide, and underlying silicon regions as indicated in the depth profiles.

FIG. 5A shows concentration profiles from a structure treated with conventional nitrogen-containing plasma over the titanium-containing layer, while FIG. 5B shows profiles from a structure treated with the thermal treatment process 10. In certain embodiment, the thermal treatment process 10 may comprise flowing a nitrogen-containing gas comprising hydrazine (N₂H₄) into the process chamber. Both profiles display similar elements including ruthenium (Ru), titanium (Ti), silicon (Si), nitrogen (N), oxygen (O), and chlorine (Cl). The chlorine concentration profile, particularly at the interfaces, demonstrates that the thermal treatment process 10 achieves higher chlorine removal effectiveness than the plasma treatment method. In one or more embodiments, the suppressed chlorine concentration throughout the profile indicates efficient removal of residual chlorine from previous processing steps. The SIMS data confirms that the thermal treatment approach may effectively remove chlorine from the metal-containing layer 130.

FIGS. 6A and 6B present X-ray Photoelectron Spectroscopy (XPS) depth profiles comparing nitrogen incorporation between different treatment methods in similar contact structures of FIGS. 5A and 5B, in accordance with an embodiment. The depth profiles plot elemental concentrations versus depth through the contact structure, revealing the distribution of elements including O, Ti, N, Si, and Ru.

FIG. 6A shows concentration profiles from a structure treated with conventional nitrogen-containing plasma, exhibiting relatively high nitrogen content throughout the analyzed depth. In contrast, FIG. 6B shows profiles from a structure treated with the thermal treatment process 10, demonstrating lower nitrogen concentration while maintaining sufficient surface coverage for oxidation protection. The reduced nitrogen content achieved by the thermal treatment is particularly advantageous as excessive nitrogen incorporation can adversely affect contact resistance. In one or more embodiments, the XPS data confirms that thermal treatment process 10 successfully forms a protective nitrogen cap layer while avoiding the over-nitridation that may be associated with plasma treatments. The oxygen profiles in both cases demonstrate effective oxidation suppression, indicating that the lower nitrogen content from thermal treatment remains sufficient for surface protection.

FIGS. 7A and 7B present depth profile analyses comparing oxygen and nitrogen concentrations in the metal-containing layer 130 after air exposure, but prior to the deposition of the metal layer 140. Multiple treatment conditions are compared: reference treatment 702 represents no nitrogen treatment, NH₃ treatment 704 is a nitrogen treatment using NH₃ gas, plasma treatment 706 is a nitrogen treatment using nitrogen-containing plasma, and thermal treatment 708 represents the thermal treatment process 10 using the gas comprising N₂H₄.

FIG. 7A shows oxygen concentration profiles for all four conditions. The thermal treatment 708 using N₂H₄ demonstrates the lowest oxygen incorporation after air exposure, indicating superior oxidation resistance compared to other treatments. The reference treatment 702 shows highest oxygen content, while NH₃ treatment 704 and plasma treatment 706 show intermediate levels of oxygen incorporation. In one or more embodiments, FIG. 7B presents corresponding nitrogen concentration profiles, where the thermal treatment 708 exhibits nitrogen content comparable with the NH₃ treatment 704, and lower than that of the plasma treatment 706. These results confirm that the thermal treatment process 10 using N₂H₄ gas achieves optimal surface protection with minimal nitrogen content, successfully preventing oxidation during air exposure while maintaining lower nitrogen incorporation compared to conventional treatment methods.

FIGS. 8A-8F illustrate cross-sectional views of process steps for processing a substrate with high aspect ratio feature, in accordance with an embodiment. The substrate 800 may comprise a substrate layer 802, which may comprise the materials and structures as described with reference to the substrate layer 102. A layer to-be-etched 804 may be disposed over the substrate layer 802. A patterned mask layer 806 may be disposed over the layer to-be-etched 804.

In various embodiments, the layer to-be-etched 804 may comprise semiconductor materials, dielectric materials, metallic materials, or combinations thereof. The semiconductor materials may include silicon, germanium, silicon-germanium compounds, III-V compound semiconductors, II-VI compound semiconductors, or other semiconductor materials. The dielectric materials may include silicon oxide, silicon nitride, silicon oxynitride, high-k dielectric materials, low-k dielectric materials, or other insulating materials. The metallic materials may include pure metals, metal alloys, metal nitrides, metal silicides, or other conductive materials. In one or more embodiments, the layer to-be-etched 804 may be formed using deposition techniques including chemical vapor deposition, physical vapor deposition, atomic layer deposition, epitaxial growth, or other suitable methods.

In one or more embodiments, the patterned mask layer 806 may comprise openings 807 that expose portions of the underlying layer to-be-etched 804. The patterned mask layer 806 may serve as an etch mask in subsequent processing steps. In various embodiments, the patterned mask layer 806 may comprise organic materials, inorganic materials, or combinations thereof. Organic mask materials may include photoresist materials, bottom anti-reflective coatings (BARC), spin-on carbon materials, amorphous carbon, hardmask organic materials, or other carbon-based materials. Inorganic mask materials may include silicon oxide, silicon nitride, silicon oxynitride, silicon carbide, metal oxides, metal nitrides, or other inorganic compounds. In one or more embodiments, the mask layer may comprise multiple layers forming a composite stack, such as tri-layer masks combining organic and inorganic materials, or hybrid masks incorporating different material properties.

The patterned mask layer 806 may be formed through various techniques including photolithography, electron beam lithography, nanoimprint lithography, or other patterning methods. The thickness and composition of the patterned mask layer 806 may be selected based on etch selectivity requirements, pattern transfer fidelity, and integration considerations.

In FIG. 8B, an etching process may be applied to the substrate 800. In various embodiments, the layer to-be-etched 804 may be etched through the opening 807 of the patterned mask layer 806 to form an etched layer 808. In one or more embodiments, the etching process may form an opening 810 in the etched layer 808. In various embodiments, the opening 810 may be formed as a high aspect ratio feature such as a trench or via, wherein the feature comprises a width to depth ratio between 1:5 and 1:20. The high aspect ratio feature may serve as contact holes, interconnect trenches, or other device structures.

The etching process may be performed using various techniques including reactive ion etching (RIE), plasma etching, deep reactive ion etching (DRIE), atomic layer etching (ALE), or other directional etching methods. The etch chemistry may be selected to provide high selectivity between the layer to-be-etched 804 and the patterned mask layer 806. In one or more embodiments, the etch process may utilize fluorine-based, chlorine-based, bromine-based chemistries, or combinations thereof, depending on the composition of the layer to-be-etched 804. Process parameters such as gas flows, pressure, power, and temperature may be controlled to achieve desired feature profiles with vertical sidewalls.

In FIG. 8C, after the etching process, the patterned mask layer 806 may be removed, leaving the etched layer 808 in the substrate. In various embodiments, the mask removal process depends on the composition of the patterned mask layer 806. For organic mask materials, removal methods may include oxygen-based plasma ashing, hydrogen-based plasma stripping, wet chemical stripping using organic solvents, or combinations thereof. For inorganic mask materials, removal may be performed using wet chemical etching with selective etchants, dry etching processes, or vapor-based chemical removal techniques.

FIG. 8D illustrates a cross-sectional view showing formation of a first metal-containing layer 812 over surfaces of the etched layer 808. In various embodiments, the first metal-containing layer 812 may be conformally deposited over both sidewalls and bottom surfaces of the opening 810. In various embodiments, the first metal-containing layer 812 may comprise similar materials and be formed using similar techniques as described with reference to the metal-containing layer 130 in FIG. 1B.

In FIG. 8E, a thermal treatment process 80 may be applied to the substrate 800. In various embodiments, the thermal treatment process 80 may utilize similar conditions and nitrogen-containing gases as described for the thermal treatment process 10 described in FIG. 1C, including hydrazine (N₂H₄), ammonia (NH₃), nitrogen (N₂), methylhydrazine, dimethylhydrazine, or the like. In some embodiments, the process temperature may be maintained between 100 °C and 400 °C, with gas flow rates between 50 sccm and 200 sccm. The thermal treatment process 80 may remove halogen (e.g., chlorine) from the first metal-containing layer 812, converting it to a treated layer 822. The removal of halogen contamination may enhance surface reactivity and promote higher deposition rates in subsequent processing steps. In one or more embodiments, the thermal treatment process 80 may incorporate controlled amounts of nitrogen into the first metal-containing layer 812.

The thermal treatment process 80 may advantageously provide homogeneous treatment across all surfaces of the first metal-containing layer 812 (or the treated layer 822), including top surfaces 840, sidewalls 842, and bottom surfaces 844. Unlike plasma-based treatments (as illustrated in FIG. 9) which may have limited penetration into high aspect ratio features, the thermal gas-phase process ensures uniform access to all surfaces regardless of feature depth or geometry. This homogeneous surface treatment enables consistent properties of the treated layer 822 throughout the feature profile. In one or more embodiments, the uniform surface modification achieved by the thermal treatment process 80 is particularly important for subsequent material deposition steps, as it promotes conformal growth and uniform fill of the high aspect ratio features without variations in growth rate or material properties between top, sidewall, and bottom surfaces.

FIG. 9 illustrates a cross-sectional view demonstrating the limitations of conventional plasma treatment 90 when applied to high aspect ratio features, in accordance with an embodiment. In various embodiments, plasma species may have limited access to the sidewalls 842 of opening 810 due to the directional nature of plasma and geometrical shadowing effects. While the plasma treatment 90 may effectively process top surface 840 and portions of bottom surface 844, the treatment becomes less effective along sidewalls 842, particularly in deeper portions of the high aspect ratio feature.

This limited plasma accessibility may result in inhomogeneous surface treatment of the first metal-containing layer 812. The non-uniform treatment may lead to varying degrees of chlorine removal and nitrogen incorporation between different surfaces of the feature. In one or more embodiments, the top portions of sidewalls 842 may receive more plasma exposure than deeper regions, creating a gradient in surface properties along the feature depth. Such inhomogeneous treatment can adversely affect subsequent material deposition, potentially causing non-uniform growth rates and incomplete fill of the high aspect ratio features. This limitation of plasma treatment 90 contrasts with the uniform access provided by the thermal treatment process 80 described in FIG. 8E, which enables homogeneous surface modification regardless of feature geometry.

In FIG. 8F, a second metal-containing layer 850 may be deposited over the first metal-containing layer 812 (or the treated layer 822). Due to the homogeneous surface treatment achieved by the thermal treatment process 80, the second metal-containing layer 850 may exhibit consistent growth rates across all surfaces of the treated layer 822, including top surfaces 840, sidewalls 842, and bottom surfaces 844.

In various embodiments, the enhanced surface reactivity and uniform properties of treated layer 822 enable higher deposition rates while maintaining consistency across all surfaces. This combination of increased growth rate and uniform deposition helps prevent void formation during fill of the high aspect ratio features (e.g. the opening 810), which is particularly critical for advanced device structures. The second metal-containing layer 850 may comprise similar materials and be deposited using similar methods as described for the metal-containing layer 130 in FIG. 1B.

FIG. 10 illustrates a flow diagram of a method for forming contact structures in a semiconductor device, in accordance with an embodiment. At block 1002, a substrate may be received which may be the substrate 100 as described with reference to FIG. 1A. In various embodiments, the substrate may comprise the fin features 105 with epitaxially grown silicon-containing layer 106 comprising doped silicon, SiGe, SiP, or combinations thereof.

At block 1004, the silicon-containing layer may comprise an oxide layer over the surface. The oxide layer may be removed following the methods as described in reference to FIGS. 3A-3B. For example, the oxide layer may be removed using chemical oxide removal (COR) or other selective oxide etching processes.

At block 1006, a metal-containing layer may be deposited over the silicon-containing layer. As described in reference to FIG. 1B, the metal-containing layer may comprise titanium, zirconium, niobium, hafnium, molybdenum, tungsten, nickel, or tantalum, and deposited using various techniques including PVD, ALD, or CVD methods with metal halide precursors.

At block 1008, a thermal treatment of the metal-containing layer may be performed while exposing to a nitrogen-containing gas. The thermal treatment may follow the methods and conditions of the thermal treatment process 10 as described in reference to FIG. 1C. In various embodiments, the nitrogen-containing gas may comprise similar gases as described above with reference to FIG. 1C. The thermal treatment may remove halogen (e.g., chlorine) and incorporate nitrogen either at the surface (FIG. 1C) or throughout the metal-containing layer (FIG. 4).

At block 1010, a metal layer may be deposited over the treated metal-containing layer. The metal layer may comprise similar materials of the metal layer 140 as described in reference to FIG. 1D.

The process flow diagram of FIG. 10 illustrates primary steps in the contact formation method, however additional processing steps, variations, and materials discussed in reference to FIGS. 1A to 4 may also be incorporated. For example, the silicon-containing layer may be part of a FinFET structure including the gate structure 202 and spacer layers 204 as shown in FIG. 2. In various embodiments, intermediate steps between the illustrated blocks may include cleaning processes, chamber purging operations, transfers between process chambers, or plasma treatments when needed. The specific materials, process conditions, and treatment parameters may be selected from the ranges and options previously described.

FIG. 11 illustrates a flow diagram of a method for forming contact structures in high aspect ratio features, in accordance with an embodiment. At block 1102, a substrate is received comprising a patterned mask layer disposed over a layer to-be-etched. As described in reference to FIG. 8A, the patterned mask layer 806 may comprise organic or inorganic materials, while the layer to-be-etched 804 may comprise semiconductor, dielectric, or metallic materials.

At block 1104, the layer to-be-etched may be etched through the patterned mask layer. The etching process and resulted etched layer may follow the description in reference to FIG. 8B. In various embodiments, the etching process may form a feature with a high aspect ratio between 1:5 and 1:20 in the etched layer. Further as shown in FIG. 8C, the patterned mask layer may be subsequently removed.

At block 1106, a first metal-containing layer is formed over surfaces of the etched layer. As described in reference to FIG. 8D, the first metal-containing layer may be conformally deposited over sidewalls and bottom surfaces of the high aspect ratio feature using various deposition techniques.

At block 1108, the substrate is exposed to a nitrogen-containing gas to remove chlorine in the first metal-containing layer. The treatment process at block 1108 may use the conditions and nitrogen-containing gas used in the thermal treatment process 80 as described in reference to FIG. 8E. The thermal treatment process with exposure to the nitrogen-containing gas may provide homogeneous treatment across top surfaces, sidewalls, and bottom surfaces of the first metal-containing layer. In various embodiments, the thermal treatment process may remove halogen (e.g., chlorine) from the metal-containing layer and incorporate nitrogen to the metal-containing layer as described in FIG. 8E.

At block 1110, a second metal-containing layer may be deposited over the first metal-containing layer. The materials and processes of forming the second metal-containing layer may be similar to the descriptions in reference to FIG. 8F, where the second metal-containing layer 850 exhibits uniform growth rates across all surfaces due to the homogeneous treatment, resulting in void-free fill of the high aspect ratio features.

The process flow diagram of FIG. 11 illustrates primary steps in forming metal contacts in high aspect ratio features, however additional processing steps, variations, and materials discussed in reference to FIGS. 8A to 8F may also be incorporated. For example, the layer to-be-etched may comprise various materials including semiconductors, dielectrics, or metals, and the patterned mask layer may include different organic or inorganic materials or multiple layer stacks. In various embodiments, intermediate steps between the illustrated blocks may include cleaning processes, surface preparations, chamber purging operations, or transfers between process chambers.

While the foregoing description often references chlorine as an exemplary halogen element, the disclosed processes and methods are equally applicable to other halogen elements including fluorine, bromine, and iodine. In various embodiments, the thermal treatment process using nitrogen-containing gases effectively removes these other halogen elements from metal-containing layers when present. The specific halogen element involved depends on the particular metal halide precursor used during deposition, which may include metal fluorides, metal chlorides, metal bromides, or metal iodides. The mechanisms of halogen removal and nitrogen incorporation described herein function similarly across different halogen species, though specific process parameters such as temperature and treatment duration may be optimized based on the particular halogen element present. This broad applicability enables the thermal treatment process to address halogen contamination regardless of which metal halide precursor chemistry is employed in the fabrication process.

Example embodiments of the invention are described below. Other embodiments can also be understood from the entirety of the specification as well as the claims filed herein.
Example 1. A method for processing a substrate, the method including: loading a substrate in a process chamber, the substrate includes a recessed feature and a silicon-containing layer disposed at bottom of the recessed feature; forming a metal-containing layer over the silicon-containing layer, the metal-containing layer including a surface layer including halogen; exposing the metal-containing layer to a nitrogen-containing gas to remove the halogen from the surface layer; and forming a metal layer over the metal-containing layer, where the metal layer fills the recessed feature.
Example 2. The method of example 1, further including removing an oxide layer formed over the silicon-containing layer before forming the metal-containing layer.
Example 3. The method of one of examples 1 or 2, where forming the metal-containing layer includes exposing the substrate to a metal chloride precursor.
Example 4. The method of one of examples 1 to 3, where the exposing includes: maintaining the process chamber at a temperature between 100 °C and 400 °C; and flowing the nitrogen-containing gas over the substrate.
Example 5. The method of one of examples 1 to 4, where the nitrogen-containing gas includes hydrazine (N₂H₄).
Example 6. The method of one of examples 1 to 5, where the exposing adds nitrogen into the metal-containing layer.
Example 7. The method of one of examples 1 to 6, where the metal-containing layer includes zirconium, niobium, hafnium, molybdenum, titanium, tungsten, nickel, or tantalum.
Example 8. The method of one of examples 1 to 7, where the metal layer includes tungsten, copper, ruthenium, or molybdenum.
Example 9. A method for processing a substrate, the method including: providing a substrate including a silicon-containing layer in a process chamber; forming a metal-containing layer over the silicon-containing layer; annealing the metal-containing layer to form a titanium silicide layer; performing a thermal process in the absence of plasma, the performing including exposing the titanium silicide layer to a nitrogen-containing gas to form a nitrogen-containing surface layer in the titanium silicide layer; and forming a metal layer over the nitrogen-containing surface layer.
Example 10. The method of example 9, further including performing an oxide removal process on surfaces of the silicon-containing layer before forming the metal-containing layer.
Example 11. The method of one of examples 9 or 10, where the metal-containing layer includes zirconium, niobium, hafnium, molybdenum, titanium, tungsten, nickel, or tantalum.
Example 12. The method of one of examples 9 to 11, where the metal layer includes tungsten, copper, ruthenium, or molybdenum.
Example 13. The method of one of examples 9 to 12, where the nitrogen-containing gas includes hydrazine (N₂H₄).
Example 14. The method of one of examples 9 to 13, where the temperature of the process chamber is elevated between 100 °C and 400 °C.
Example 15. The method of one of examples 9 to 14, where a flow rate of the nitrogen-containing gas is between 50 sccm and 200 sccm.
Example 16. A method for processing a substrate, the method including: loading a substrate in a process chamber, the substrate includes a patterned mask layer disposed over a layer to-be-etched; etching the layer to-be-etched through an opening of the patterned mask layer to form an etched layer; forming a first metal-containing layer over surfaces of the etched layer, the first metal-containing layer including halogen; exposing the substrate to a nitrogen-containing gas to remove the halogen from the first metal-containing layer; and depositing a second metal-containing layer over the first metal-containing layer.
Example 17. The method of example 16, where the first metal-containing layer includes zirconium, niobium, hafnium, molybdenum, titanium, tungsten, nickel, or tantalum.
Example 18. The method of one of examples 16 or 17, where the nitrogen-containing gas includes hydrazine (N₂H₄).
Example 19. The method of one of examples 16 to 18, where the exposing adds nitrogen into the first metal-containing layer.
Example 20. The method of one of examples 16 to 19, where the etched layer includes an opening with width to depth ratio between 1:5 and 1:20.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-4, 8A-11 may be combined in further embodiments. It is therefore intended that the appended claims encompass any such modifications or embodiments.

What is claimed is:

1. A method for processing a substrate, the method comprising:
loading a substrate in a process chamber, the substrate comprises a recessed feature and a silicon-containing layer disposed at bottom of the recessed feature;
forming a metal-containing layer over the silicon-containing layer, the metal-containing layer comprising a surface layer comprising halogen;
exposing the metal-containing layer to a nitrogen-containing gas to remove the halogen from the surface layer; and
forming a metal layer over the metal-containing layer, wherein the metal layer fills the recessed feature.

2. The method of claim 1, further comprising removing an oxide layer formed over the silicon-containing layer before forming the metal-containing layer.

3. The method of claim 1, wherein forming the metal-containing layer comprises exposing the substrate to a metal chloride precursor.

4. The method of claim 1, where the exposing comprises:
maintaining the process chamber at a temperature between 100 °C and 400 °C; and
flowing the nitrogen-containing gas over the substrate.

5. The method of claim 1, wherein the nitrogen-containing gas comprises hydrazine (N₂H₄).

6. The method of claim 1, wherein the exposing adds nitrogen into the metal-containing layer.

7. The method of claim 1, wherein the metal-containing layer comprises zirconium, niobium, hafnium, molybdenum, titanium, tungsten, nickel, or tantalum.

8. The method of claim 1, wherein the metal layer comprises tungsten, copper, ruthenium, or molybdenum.

9. A method for processing a substrate, the method comprising:
providing a substrate comprising a silicon-containing layer in a process chamber;
forming a metal-containing layer over the silicon-containing layer;
annealing the metal-containing layer to form a titanium silicide layer;
performing a thermal process in the absence of plasma, the performing comprising exposing the titanium silicide layer to a nitrogen-containing gas to form a nitrogen-containing surface layer in the titanium silicide layer; and
forming a metal layer over the nitrogen-containing surface layer.

10. The method of claim 9, further comprising performing an oxide removal process on surfaces of the silicon-containing layer before forming the metal-containing layer.

11. The method of claim 9, wherein the metal-containing layer comprises zirconium, niobium, hafnium, molybdenum, titanium, tungsten, nickel, or tantalum.

12. The method of claim 11, wherein the metal layer comprises tungsten, copper, ruthenium, or molybdenum.

13. The method of claim 9, wherein the nitrogen-containing gas comprises hydrazine (N₂H₄).

14. The method of claim 12, wherein the temperature of the process chamber is elevated between 100 °C and 400 °C.

15. The method of claim 12, wherein a flow rate of the nitrogen-containing gas is between 50 sccm and 200 sccm.

16. A method for processing a substrate, the method comprising:
loading a substrate in a process chamber, the substrate comprises a patterned mask layer disposed over a layer to-be-etched;
etching the layer to-be-etched through an opening of the patterned mask layer to form an etched layer;
forming a first metal-containing layer over surfaces of the etched layer, the first metal-containing layer comprising halogen;
exposing the substrate to a nitrogen-containing gas to remove the halogen from the first metal-containing layer; and
depositing a second metal-containing layer over the first metal-containing layer.

17. The method of claim 16, wherein the first metal-containing layer comprises zirconium, niobium, hafnium, molybdenum, titanium, tungsten, nickel, or tantalum.

18. The method of claim 16, wherein the nitrogen-containing gas comprises hydrazine (N₂H₄).

19. The method of claim 16, wherein the exposing adds nitrogen into the first metal-containing layer.

20. The method of claim 16, wherein the etched layer comprises an opening with width to depth ratio between 1:5 and 1:20.
